(19) United States
(12) Patent Application Publication
(10) Pub. No.: US 2024/0396292 A1
(43) Pub. Date: Nov. 28, 2024

(54) OPTICAL SCANNING DEVICE AND IMAGE FORMING DEVICE

(71) Applicant: SHARP KABUSHIKI KAISHA, Sakai City (JP)

(72) Inventors: ATSUO NAKAO, Sakai City (JP); Hiroaki Goi, Sakai City (JP); Hiroshi Yamamoto, Sakai City (JP)

(21) Appl. No.: 18/670,626

(22) Filed: May 21, 2024

(30) Foreign Application Priority Data
May 24, 2023 (JP) 2023-085720

(51) Int. Cl. H01S 5/02315; B41J 2/44; B41J 2/47; G03G 15/01; G03G 15/04; G03G 15/043

(52) U.S. Cl. CPC H01S 5/02315; B41J 2/442; B41J 2/471; G03G 15/011; G03G 15/0189; G03G 15/04036; G03G 15/0435

(57) ABSTRACT

An optical scanning device includes a laser diode that emits a light beam, a holder to which the laser diode is fixed, and a holding unit that holds and arranges a plurality of holders side by side. The holder includes a first end portion and a second end portion that face each other across a center of the holder, and a first side portion and a second side portion that linearly extend from the first end portion toward the second end portion. The first side portion and the second side portion extend such that a distance therebetween gradually increases from the first end portion toward the second end portion. The adjacent ones of the holders in a state of being held by the holding unit are disposed such that the second end portion of the other holder is adjacent to the first end portion of one holder.

### CROSS-REFERENCE TO RELATED APPLICATION

The present application claims priority from Japanese Application JP2023-085720,the content to which is hereby incorporated by reference into this application.

The disclosure relates to an optical scanning device and an image forming device including a holder to which a laser diode is fixed.

In the related art, an optical scanning device for scanning with a laser beam is used in an image forming device such as a digital copying machine, a laser printer, or a facsimile machine. When an image is formed by the image forming device, after a photoreceptor is charged by a charging device, writing according to image information is performed by the optical scanning device, and an electrostatic latent image is formed on the photoreceptor. Then, the electrostatic latent image on the photoreceptor is developed by toner supplied from a developing device. The toner image developed on the photoreceptor is transferred to a sheet by a transfer device, and further fixed to the sheet by a fixing device, so that a desired image can be obtained.

A laser diode serving as a light source of the optical scanning device is mounted to a predetermined holding unit. As the holding unit, for example, a wall portion of a housing serving as a housing of the optical scanning device is applied, and the laser diode is fixed to the holding unit via a holder. The laser diodes are arranged close to each other in a height direction and are arranged side by side in an inclined manner.

### SUMMARY OF THE INVENTION

In the known optical scanning device, a laser diode holder has a circular shape. In order to improve optical performance such as a beam size, it is necessary to arrange the laser diodes close to each other in the height direction. However, in the known optical scanning device, since the laser diode holder has the circular shape, when a plurality of the laser diode holders are arranged close to each other, the laser diode holders interfere with each other, and thus the arrangement of the laser diode holders is limited. Thus, there is a problem in that a plurality of laser diodes cannot be densely arranged.

The disclosure has been made to solve the above-described problem, and an object of the disclosure is to provide an optical scanning device and an image forming device in which the plurality of laser diodes can be densely arranged.

An optical scanning device according to the disclosure includes a laser diode that emits a light beam; a holder to which the laser diode is fixed; and a holding unit that holds and arranges a plurality of the holders side by side, in which the holder includes a first end portion and a second end portion that face each other across a center of the holder, and a first side portion and a second side portion that extend linearly from the first end portion toward the second end portion, the first side portion and the second side portion extend such that a distance therebetween gradually increases from the first end portion toward the second end portion, and the adjacent ones of the holders in a state of being held by the holding unit are disposed such that the second end portion of the other holder is adjacent to the first end portion of one of the holders.

In the optical scanning device according to the disclosure, the plurality of holders may be linearly arranged in the height direction in the holding unit.

In the optical scanning device according to the disclosure, a protruding portion gripped by a jig may be provided on a surface of the holder.

In the optical scanning device according to the disclosure, a notch portion into which the jig is inserted may be provided on an outer edge of the holder.

In the optical scanning device according to the disclosure, the holder may be adhered to the holding unit via adhesive portions provided at the first end portion and the second end portion.

In the optical scanning device according to the disclosure, the adjacent ones of the holders in a state of being held by the holding unit may be disposed such that the first side portions thereof face each other and the second side portions thereof face each other.

In the optical scanning device according to the disclosure, the adjacent ones of the holders in the state of being held by the holding unit may be arranged such that one end portions thereof are staggered in an arrangement order.

In the optical scanning device according to the disclosure, the holder may have a fan shape.

In the optical scanning device according to the disclosure, the holder may have a triangular shape.

In the optical scanning device according to the disclosure, the holder may have a trapezoidal shape.

An image forming device according to the disclosure includes the optical scanning device according to the disclosure.

According to the disclosure, in adjacent ones of holders in a holding unit, one holder is rotated by 180° with respect to the other holder, and first end portions each having a small width and second end portions each having a large width are arranged to be staggered. Thus, in the holding unit, a plurality of the holders (laser diodes) can be arranged close to each other, and a distance between light beams emitted from the laser diodes can be reduced. Then, the light beams are concentrated, so that the number of optical components such as lenses can be reduced and the optical components can be downsized.

### BRIEF DESCRIPTION OF THE DRAWINGS

FIG. 1 is a schematic side view of an image forming device according to an embodiment of the disclosure.

FIG. 2 is a perspective view illustrating an optical scanning device according to the embodiment of the disclosure.

FIG. 3 is a plan view illustrating an optical scanning device according to the embodiment of the disclosure.

FIG. 4 is a schematic enlarged view illustrating the vicinity of a holding unit in a comparative example.

FIG. 5 is a perspective view illustrating a holder according to the embodiment of the disclosure.

FIG. 6 is a plan view illustrating the holder according to the embodiment of the disclosure.

FIG. 7 is a plan view illustrating the holder held by a jig.

FIG. 8 is an enlarged plan view illustrating the vicinity of a holding unit according to the embodiment of the disclosure.

FIG. 9 is a schematic perspective view illustrating a positional relationship of optical components in an optical scanning device.

FIG. 10 is a schematic perspective view illustrating a positional relationship of the optical components in the optical scanning device.

### DETAILD DESCRIPTION OF THE INVENTION

An image forming device according to an embodiment of the disclosure will be described with reference to the accompanying drawings.

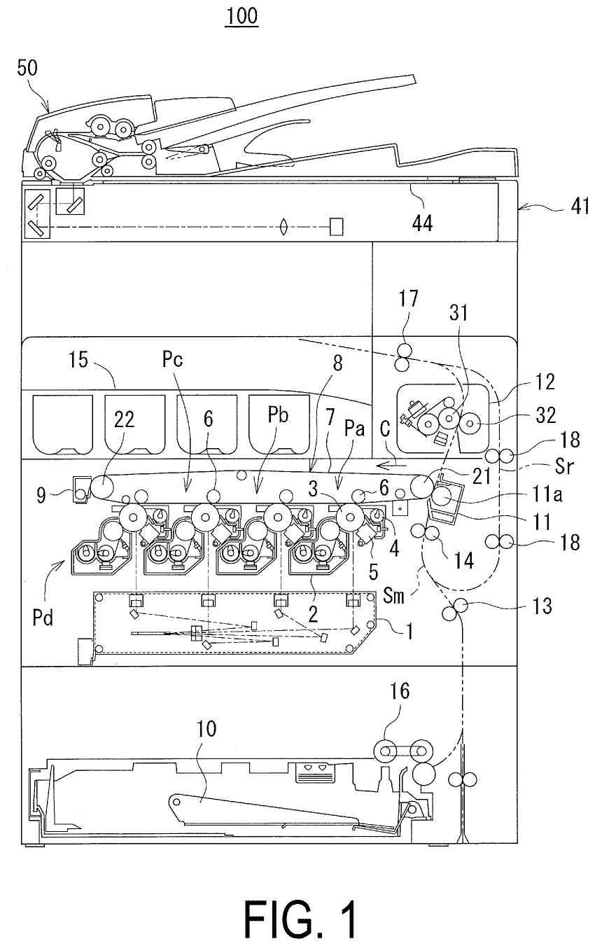

FIG. 1 is a schematic side view of the image forming device according to the embodiment of the disclosure.

An image forming device 100 is a multifunction printer having a scanner function, a copy function, a printer function, and a facsimile function, and is configured to transmit an image of a document scanned by an image scanning device to an external device (corresponding to the scanner function), and form an image of a scanned document or an image received from an external device on a sheet in color or black and white (corresponding to the copy function, the printer function, and the facsimile function).

A document feeding device 50 (automatic document feeder (ADF)) supported in an openable/closable manner by an image scanner 41 is provided on an upper side of the image scanner 41. When the document feeding device 50 is opened, a document table 44 above the image scanner 41 is opened, and a document can be manually placed on the image scanner 41. In addition, the document feeding device 50 automatically feeds a placed document onto the image scanner 41. The image scanner 41 scans the placed document or a document fed from the document feeding device 50 to generate image data. An image forming device 100 includes an optical scanning device 1, a development device 2, a photoreceptor drum 3, a drum cleaning device 4, a charger 5, an intermediate transfer belt 7, a fixing device 12, a sheet feeding path Sm, a feed cassette 10, and a stacking tray 15.

The image forming device 100 handles image data corresponding to a color image composed of the colors black (K), cyan (C), magenta (M), and yellow (Y), or a monochrome image composed of a single color (black, for example). The image forming device 100 is provided with four sets of the development device 2, four sets of the photoreceptor drum 3, four sets of the drum cleaning device 4, and four sets of the charger 5 that form four types of toner images, with the sets respectively serving as image stations Pa, Pb, Pc, Pd corresponding to the colors black, cyan, magenta, and yellow, respectively.

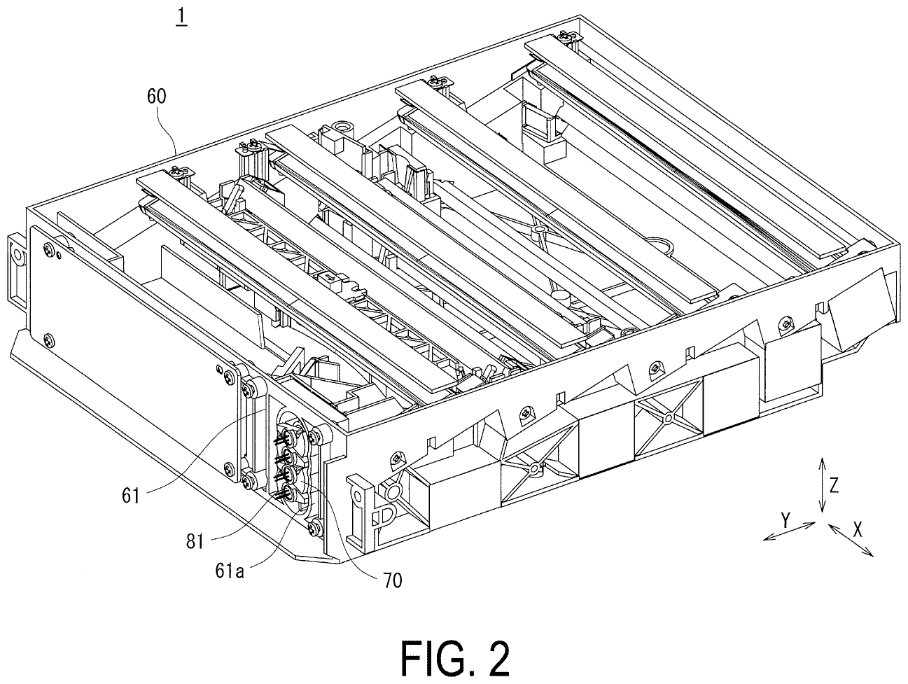

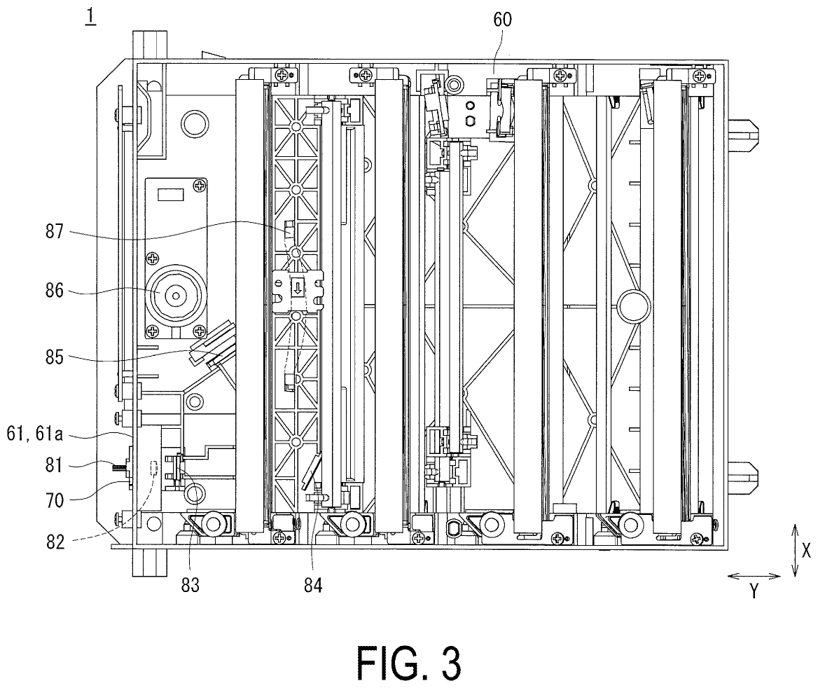

The drum cleaning device 4 removes and collects residual toner on the front surface of the photoreceptor drum 3. The charger 5 uniformly charges a front surface of the photoreceptor drum 3 to a predetermined potential. The optical scanning device 1 exposes the front surface of the photoreceptor drum 3 to form an electrostatic latent image. The development device 2 develops the electrostatic latent image on the front surface of the photoreceptor drum 3 to form a toner image on the front surface of the photoreceptor drum 3. With this series of operations, a toner image of each color is formed on the front surface of each photoreceptor drum 3. Note that a detailed structure of the optical scanning device 1 will be described with reference to FIG. 2 and FIG. 3 described below.

A transfer belt device 8 is provided above the photoreceptor drum 3, and an intermediate transfer roller 6 is disposed via the intermediate transfer belt 7. The intermediate transfer belt 7 is stretched around a transfer driving roller 21 and a transfer driven roller 22 and is rotated in the direction of an arrow C, the residual toner is removed and collected by a belt cleaning device 9, and the toner images of respective colors formed on the respective surfaces of the photoreceptor drums 3 are sequentially transferred and superimposed to form a color toner image on the surface of the intermediate transfer belt 7.

A transfer roller 11a of a secondary transfer device 11 forms a nip region with the intermediate transfer belt 7, and a sheet fed through the sheet feeding path Sm is fed while being nipped in the nip region. When the sheet passes through the nip region, the toner image on the surface of the intermediate transfer belt 7 is transferred to the sheet and the sheet is fed to the fixing device 12.

The fixing device 12 includes a fixing roller 31 and a pressure roller 32 that rotate across the sheet. In the fixing device 12, the sheet with the transferred toner image is nipped between the fixing roller 31 and the pressure roller 32 and subject to heat and pressure to fix the toner image onto the sheet.

The feed cassette 10 is a cassette for storing the sheets to be used for image formation, and is provided below the optical scanning device 1. The sheet is pulled out from the sheet feeding cassette 10 by a pickup roller 16, is fed through the sheet feeding path Sm, passes through the secondary transfer device 11 and the fixing device 12, and is fed out onto the stacking tray 15 via sheet discharge rollers 17. In the sheet feeding path Sm, there are disposed registration rollers 14, conveying rollers 13, and the sheet discharge rollers 17. The registration rollers 14 temporarily stop the sheet to align a distal end of the sheet, and subsequently resume feeding of the sheet in synchronization with a transfer timing of the toner images in the nip region between the intermediate transfer belt 7 and the transfer roller 11a. The conveying rollers 13 urge feeding of the sheet.

When forming an image on both the front surface and the back surface of the sheet, the sheet is conveyed in the reverse direction from the discharge rollers 17 to a sheet reverse path Sr. In the sheet reverse path Sr, the sheet is reversed by reversing rollers 18 and is guided again to the sheet registration rollers 14. Thereafter, an image is formed on the back surface in the same manner as the front surface, and the sheet is fed out onto the stacking tray 15.

FIG. 2 is a perspective view illustrating the optical scanning device according to the embodiment of the disclosure, and FIG. 3 is a plan view illustrating the optical scanning device according to the embodiment of the disclosure.

The optical scanning device 1 according to the embodiment of the disclosure includes a housing 60 having a rectangular shape, and optical components are mounted to respective portions of the housing 60. FIGS. 2 and 3 illustrate a state in which some members such as an upper surface of the housing 60 are removed so that the inside of the housing 60 can be seen for ease of viewing of the drawings. Hereinafter, for the sake of description, a direction along one side surface (for example, a mounting side surface 61) of the housing 60 may be referred to as a width direction X, a direction along a side surface adjacent to the mounting side surface 61 may be referred to as a length direction Y, and a direction orthogonal to the width direction X and the length direction Y may be referred to as a height direction Z.

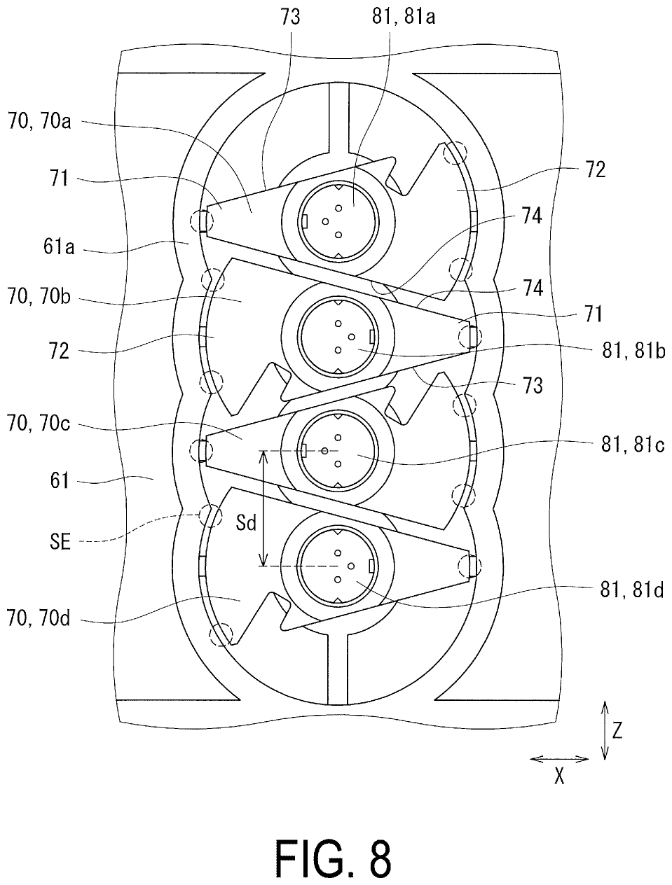

A holding unit 61a that holds a laser diode 81 and a holder 70 is provided on the mounting side surface 61 of the housing 60. Note that a relationship between the holding unit 61a and the holder 70 will be described with reference to FIG. 8 described below.

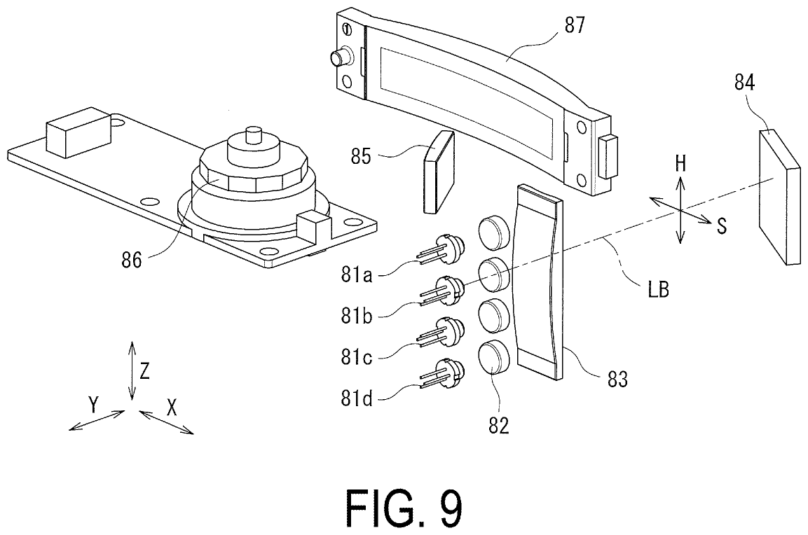

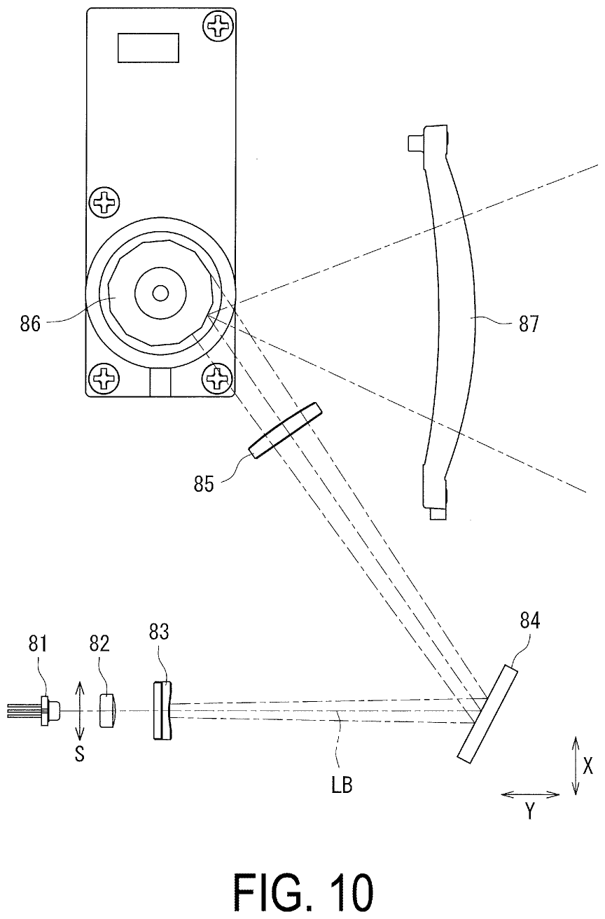

In addition to the laser diode 81 and the holder 70, optical components such as a collimator lens 82, a first expander lens 83, a reflection mirror 84, a second expander lens 85, a polygon mirror 86 (rotary polygon mirror), and an fθ lens 87 are mounted to the housing 60. Not limited thereto, various components such as a mirror, a lens, an aperture, and a sensor may be mounted to the housing 60. The relationship between a light beam LB emitted from the laser diode 81 and the optical components will be described later with reference to FIG. 9 and FIG. 10.

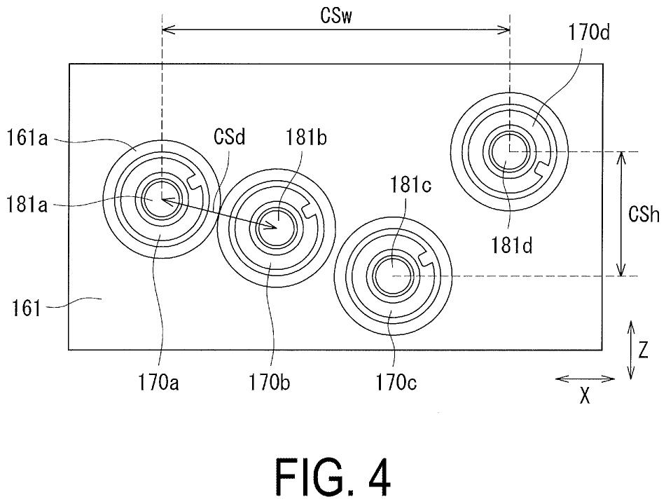

In the present embodiment, four laser diodes 81 are mounted to the housing 60, and four holders 70 are provided in correspondence with the respective laser diodes 81. Next, a mounting position of the laser diode 81 in the housing 60 will be described with reference to FIG. 4 to FIG. 8 in order to compare a comparative example based on a known structure with the present embodiment.

FIG. 4 is a schematic enlarged view illustrating the vicinity of a holding unit in the comparative example.

FIG. 4 is the comparative example based on a known structure, and illustrates an enlarged view of the vicinity of a comparative holding unit 161a on a comparative mounting side surface 161 of the housing. In the comparative example, the four laser diodes (a first comparative diode 181a to a fourth comparative diode 181d) are mounted to corresponding holders (a first comparative holder 170a to a fourth comparative holder 170d), respectively, and are held by the housing via the holders. In the comparative example, the holders (the first comparative holder 170a to the fourth comparative holder 170d) each has a substantially circular shape. The comparative holding unit 161a has a protruding portion having an annular shape corresponding to a shape of the holder, and the holder is accommodated in a recessed portion on the inner side. Although not illustrated in FIG. 4, the comparative holding unit 161a is provided with an opening facing an emission portion of the laser diodes (the first comparative diode 181a to the fourth comparative diode 181d), and the emitted light passes through the opening.

In the comparative example, three holders of the first comparative holder 170a to the third comparative holder 170c are arranged side by side, and the fourth comparative holder 170d is mounted at a position slightly away from them. Specifically, when viewed in the width direction X, the first comparative holder 170a, the second comparative holder 170b, the third comparative holder 170c, and the fourth comparative holder 170d are mounted in this order from the left, and when viewed in the height direction Z, the fourth comparative holder 170d, the first comparative holder 170a, the second comparative holder 170b, and the third comparative holder 170c are mounted in this order from above. That is, in the comparative example, the four holders are disposed so as not to overlap each other in any of the width direction X and the height direction Z.

Even when the holders are disposed close to each other, the holders interfere with each other. Thus, the holders need to be disposed separated from each other, and there is a limit to shortening a distance (comparative inter-element distance CSd) between adjacent ones of laser diodes.

When the positional relationships between the plurality of laser diodes in the width direction X and the height direction Z are viewed, the first comparative diode 181a and the fourth comparative diode 181d are disposed at the most distant positions in the width direction X, and the third comparative diode 181c and the fourth comparative diode 181d are disposed at the most distant positions in the height direction Z.

A distance (comparative inter-element width CSw) between the first comparative diode 181a and the fourth comparative diode 181d in the width direction X and a distance (comparative inter-element height CSh) between the third comparative diode 181c and the fourth comparative diode 181d in the height direction Z affect sizes and the number of optical components on which light is incident. That is, when the comparative inter-element width CSw and the comparative inter-element height CSh increase, it is necessary to increase the sizes of the optical components so that light from the plurality of laser diodes is incident on the optical components or to increase the number of optical components so as to correspond to the light from the respective laser diodes, which requires an increase in the size of the optical scanning device 1.

As described above, in the known configuration, the laser diode holder has a circular shape, and when the plurality of laser diodes are arranged close to each other in a straight line in the height direction, there is a problem in that the laser diode holders physically interfere with each other.

On the other hand, in the present embodiment, the shape of the holder 70 is made different and the plurality of laser diodes 81 are densely arranged, so that reduction of the number of the optical components and the like and downsizing of the optical scanning device 1 are achieved.

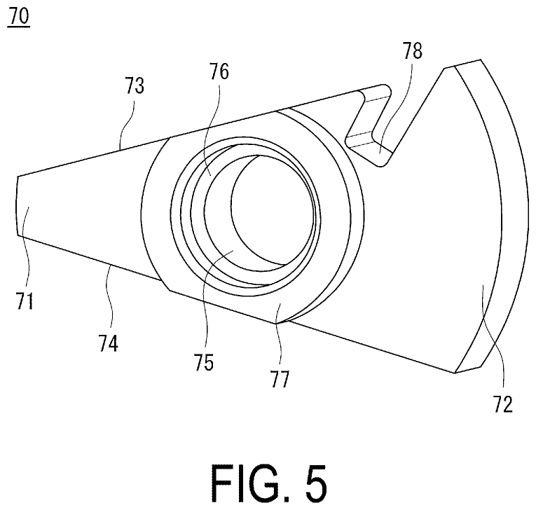

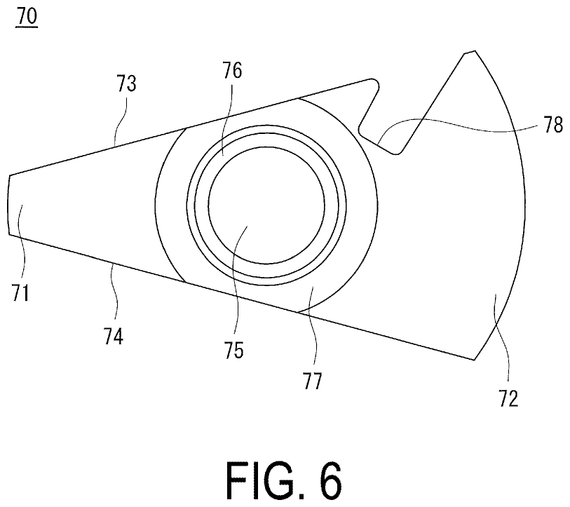

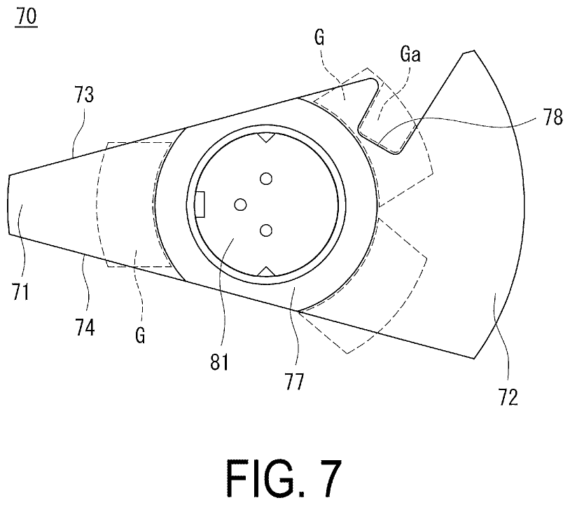

FIG. 5 is a perspective view illustrating the holder according to the embodiment of the disclosure, FIG. 6 is a plan view illustrating the holder according to the embodiment of the disclosure, and FIG. 7 is a plan view illustrating the holder held by the jig.

In the present embodiment, the holder 70 has a substantially fan shape, and includes a first end portion 71 and a second end portion 72 that face each other across a center of the holder 70, and a first side portion 73 and a second side portion 74 that linearly extend from the first end portion 71 toward the second end portion 72. The first side portion 73 and the second side portion 74 extend such that a distance therebetween gradually increases from the first end portion 71 toward the second end portion 72.

The shape of the holder 70 is not limited to the fan shape, but may be a shape including the first side portion 73 and the second side portion 74 extending between the first end portion 71 having a narrow width and the second end portion 72 having a wide width, and may be, for example, a triangular shape or a trapezoidal shape. In addition, the shape may include the first side portion 73 and the second side portion 74 extending between the first end portion 71 having no width and the second end portion 72 having a width, and may be, for example, a simple triangular shape.

An opening 75 having a circular shape into which the emission portion of the laser diode 81 is inserted is provided substantially at the center of the holder 70. A protruding portion 77 having an annular shape is provided around the opening 75 with a slight gap (element receiving portion 76) therebetween. The protruding portion 77 protrudes from a surrounding plane, and as illustrated in FIG. 7, when the holder 70 is mounted to the housing 60, the protruding portion 77 is gripped by the jig G (indicated by a broken line in FIG. 7). The element receiving portion 76 has a step with respect to the protruding portion 77 in the thickness direction of the holder 70, and receives a part of the laser diode 81.

The first side portion 73 is provided with a notch portion 78 formed by cutting out a part of the first side portion 73. When the holder 70 is gripped, s positioning claw Ga of the jig G is inserted into the notch portion 78 which is a recessed portion (see FIG. 7). In this way, when the holder 70 is mounted to the holding unit 61a, by using the notch portion 78 as a reference, positioning of the holder 70 can be performed.

FIG. 8 is an enlarged plan view illustrating the vicinity of the holding unit according to the embodiment of the disclosure.

In the present embodiment, the four laser diodes 81 (a first diode 81a to a fourth diode 81d) are mounted to corresponding holders 70 (a first holder 70a to a fourth holder 70d), respectively, and are held by the housing 60 via the holders 70.

In the holding unit 61a, the four holders 70 are arranged side by side in the height direction Z, and the first holder 70a, the second holder 70b, the third holder 70c, and the fourth holder 70d are mounted in this order from above. The holding unit 61a has a vertically long protruding portion corresponding to the shape of the four holders 70, and the four holders 70 are accommodated in a recessed portion on the inner side. In addition, on the inner side of the holding unit 61a, openings are provided at positions facing the emission portions of the first diode 81a to the fourth diode 81d, and the emitted light passes through the openings.

Specifically, focusing on the first holder 70a and the second holder 70b illustrated in FIG. 8, in the first holder 70a, the first end portion 71 is directed to one side (left side in FIG. 8) in the width direction X, and the second end portion 72 is directed to the other side (right side in FIG. 8) in the width direction X. At this time, in the first holder 70a, the first side portion 73 is located on the upper side and the second side portion 74 is located on the lower side. In the second holder 70b, the first end portion 71 is directed to the other side (right side in FIG. 8) in the width direction X, and the second end portion 72 is directed to one side (left side in FIG. 8) in the width direction X. At this time, in the second holder 70b, the second side portion 74 is located on the upper side and the first side portion 73 is located on the lower side. That is, the second holder 70b is mounted to the holding unit 61a in a state of being rotated by 180° with respect to the first holder 70a. The third holder 70c and the fourth holder 70d are mounted in the same manner as the first holder 70a and the second holder 70b, the third holder 70c is directed to the same direction as the first holder 70a, and the fourth holder 70d is directed to the same direction as the second holder 70b. That is, in the present embodiment, the plurality of holders 70 are arranged side by side such that the positions of the first end portions 71 and the second end portions 72 are staggered. A distance (inter-element distance Sd) between adjacent ones of the laser diodes 81 is shorter than the comparative inter-element distance CSd in the comparative example.

The adjacent ones of the holders 70 in a state of being held by the holding unit 61a are disposed such that the second end portion 72 of the other holder 70 is adjacent to the first end portion 71 of one holder 70. In addition, when a relationships between the side portions (the first side portion 73 and the second side portion 74) of the adjacent ones of the holders 70 are viewed in detail, the first side portions 73 are disposed to face each other and the second side portions 74 are disposed to face each other.

As in the comparative example, in the case of the holders 70 each having the circular shape, no matter how the two holders 70 are arranged, the holders 70 interfere with each other, and thus the two holders 70 cannot be brought closer to each other than a distance of about the diameter of the holder 70. On the other hand, in the present embodiment, the first end portion 71 having the narrow width and the second end portion 72 having the wide width are arranged to be staggered, so that the holders 70 can be closely packed with no gap therebetween, and the plurality of holders 70 (laser diodes 81) can be arranged close to each other. As a result, the distance between the light beams emitted from the laser diodes 81 is reduced, so that the number of optical components such as lenses can be reduced, and the optical scanning device 1 can be downsized.

The holder 70 is adhered to the holding unit 61a via adhesive portions SE (indicated by a broken line in FIG. 8) provided in the first end portion 71 and the second end portion 72. In the present embodiment, one adhesive portion SE is provided in the first end portion 71, and two adhesive portions SE are provided in the second end portion 72. The two adhesive portions SE in the second end portion 72 are preferably provided at positions as far as possible from each other. One of the two adhesive portions SE is in a position close to the first side portion 73, and the other is in a position close to the second side portion 74. As described above, a plurality of separated portions are adhered to the holding unit 61a, and thus the holder 70 can be more firmly fixed.

When the holder 70 is mounted to the holding unit 61a, alignment may be performed in a state where the holder 70 is gripped by the jig G. At the time of alignment, the light beam LB is emitted from the laser diode 81, and an incident place of the light beam LB or the like may be detected. After the mounting position of the holder 70 is finely adjusted, the holder 70 may be adhered to the holding unit 61a.

FIG. 9 is a schematic perspective view illustrating a positional relationship of the optical components in the optical scanning device. FIG. 10 is a schematic perspective view illustrating a positional relationship of the optical components in the optical scanning device. In FIGS. 9 and 10, some of the optical components in the optical scanning device 1 are extracted and illustrated for ease of viewing of the drawings.

As described above, the optical components such as the laser diode 81 (the first diode 81a to the fourth diode 81d), the collimator lens 82, the first expander lens 83, the reflection mirror 84, the second expander lens 85, the polygon mirror 86, and the fθ lens 87 are mounted to the housing 60 of the optical scanning device 1.

In FIG. 9, a part of the light beam LB emitted from the laser diode 81 (in particular, the second diode 81b) is indicated by an alternate long and short dash line. Although not illustrated in FIG. 9, the light beams LB are similarly emitted from the laser diodes 81 other than the second diode 81b. A main scanning direction S and a sub-scanning direction H given to the light beam LB are directions which are scanned with the light beam LB and correspond to directions in which light spreads. In the optical path of the light beam LB from the laser diode 81 to the reflection mirror 84, the main scanning direction S is substantially parallel to the width direction X, and the sub-scanning direction H is substantially parallel to the height direction Z. Four collimator lenses 82 are provided corresponding to the four laser diodes 81 and are disposed on the optical paths of the light beams LB emitted from the laser diodes 81, respectively.

The first expander lens 83 is disposed on the optical paths of the light beams LB emitted from the collimator lenses 82. In the present embodiment, one first expander lens 83 is provided corresponding to the four laser diodes 81. Specifically, the first expander lens 83 is a vertically long lens that is long in the height direction Z in accordance with the four laser diodes 81 arranged side by side in the height direction Z, and all the light beams LB emitted from the four laser diodes 81 are incident on the first expander lens 83. The first expander lens 83 acts on the incident light beam LB to expand an irradiation range in the main scanning direction S.

In addition, the first expander lens 83 adjusts an emitting direction (irradiation angle) of the light beam LB passing therethrough in the sub-scanning direction H. The four light beams LB having passed through the first expander lens 83 change their emitting directions so that the light beams LB converge in the sub-scanning direction H. When the four light beams LB reach the polygon mirror 86, the light beams LB most converge in the sub-scanning direction H, and after passing through the first expander lens 83, the light beams LB diffuse in the sub-scanning direction H.

As described above, in the present embodiment, the plurality of holders 70 are arranged side by side in one direction, and the positions thereof in the width direction X overlap each other. Thus, as compared with the comparative example, the laser diodes 81 are particularly densely arranged in the width direction X, which is advantageous in arrangement of the optical components and the like.

That is, when the laser diodes 81 are disposed as in the comparative example illustrated in FIG. 4, it is necessary to increase the length of the first expander lens 83 in the width direction X, to provide another first expander lens 83, or to provide a mirror or the like to converge the plurality of light beams LB. As a result, problems in that an increase in the number of components and an increase in the size of the housing 60 occur.

On the other hand, in the present embodiment, by aligning the positions of the plurality of laser diodes 81 in the width direction X and reducing the distances therebetween in the height direction Z, the plurality of laser diodes 81 can be handled by one first expander lens 83. The optical component corresponding to the plurality of light beams LB is not limited to the first expander lens 83, and an appropriate component may be selected based on the arrangement of various components and the like.

The reflection mirror 84 is disposed on the optical path of the light beam LB emitted from the first expander lens 83, and guides the reflected light beam LB to be incident on the polygon mirror 86 through the second expander lens 85.

The second expander lens 85 is disposed on the optical path from the reflection mirror 84 to the polygon mirror 86, and acts on the incident light beam LB to narrow the irradiation range in the main scanning direction S. The light beam LB having passed through the second expander lens 85 becomes parallel light maintaining a constant irradiation range.

The polygon mirror 86 is, for example, a polygon mirror having a plurality of surfaces, includes a rotary shaft that is rotated by a driver such as a motor, and reflects the incident light beam LB while rotating, so that the light beam LB scans the surface of the photoreceptor drum 3.

The fθ lens 87 is provided at a position facing the polygon mirror 86, and receives the light beam LB emitted from the polygon mirror 86. Although not illustrated, optical components such as a lens and a mirror may be provided on the optical path ahead of the fθ lens 87, and the light beam LB passing through these optical components may scan the surface of the photoreceptor drum 3. In addition, an aperture may be appropriately disposed on the optical path of the light beam LB, and the light beam LB is shaped by passing through the aperture.

As illustrated in FIG. 10, in the main scanning direction (S direction in FIG. 9, X direction in FIG. 9), an optical axis of the beam emitted from each laser diode 81 (the first diode 81a to the fourth diode 81d) from each laser diode to the polygon mirror surface is on the same straight line, in other words, the optical axes of the four beams overlap each other.

In the related art, in order to improve optical performance (beam size and the like), the laser diodes are required to be arranged close to each other in the height direction, and thus the plurality of laser diodes have been arranged side by side in an inclined manner. However, in order to employ an overfill optical system in the optical scanning device, it is necessary to incorporate an expander lens for forming a wide beam into the incident system.

Thus, when a known side by side arrangement of the plurality of laser diodes is adopted for the optical scanning device, an optical path length from each laser diode to the polygon mirror surface is different for each color beam, and thus it is necessary to arrange (four) expander lenses in a beam optical path of each laser diode in order to obtain optical performance, resulting in an increase in cost.

On the other hand, when the laser diodes are arranged in a straight line in the height direction as in the present embodiment, the optical path lengths from the respective laser diodes to the polygon mirror surface are equal to each other, and only one expander lens needs to be provided, so that cost reduction can be achieved. In the present embodiment, the overfill optical system may be employed for the optical scanning device 1.

Note that the embodiments disclosed herein are illustrative in all respects and are not the basis for a limited interpretation. Accordingly, the technical scope of the disclosure is not to be construed by the foregoing embodiments only, and is defined based on the description of the claims. In addition, meanings equivalent to the range of the claims and all changes made within the range are included.

What is claimed is:

1. An optical scanning device comprising:
a laser diode that emits a light beam;
a holder to which the laser diode is fixed; and
a holding unit that holds and arranges a plurality of the holders side by side, wherein the holder includes a first end portion and a second end portion that face each other across a center of the holder, and a first side portion and a second side portion that extend linearly from the first end portion toward the second end portion,
the first side portion and the second side portion extend such that a distance therebetween gradually increases from the first end portion toward the second end portion, and
the adjacent ones of the holders in a state of being held by the holding unit are disposed such that the second end portion of the other holder is adjacent to the first end portion of one of the holders.

2. The optical scanning device according to claim 1, wherein the plurality of holders is linearly arranged in a height direction in the holding unit.

3. The optical scanning device according to claim 1, wherein a protruding portion gripped by a jig is provided on a surface of the holder.

4. The optical scanning device according to claim 1, wherein an outer edge of the holder is provided with a notch portion into which a jig is inserted.

5. The optical scanning device according to claim 1, wherein the holder is adhered to the holding unit via adhesive portions provided at the first end portion and the second end portion.

6. The optical scanning device according to claim 1, wherein the adjacent ones of the holders in a state of being held by the holding unit are disposed such that the first side portions thereof face each other and the second side portions thereof face each other.

7. The optical scanning device according to claim 1, wherein the adjacent ones of the holders in a state of being held by the holding unit are arranged such that one end portions thereof are staggered in an arrangement order.

8. The optical scanning device according to claim 1, wherein the holder has a fan shape.

9. The optical scanning device according to claim 1, wherein the holder has a triangular shape.

10. The optical scanning device according to claim 1, wherein the holder has a trapezoidal shape.

11. An image forming device, comprising:
the optical scanning device according to claim 1.
